(19) United States
(12) Patent Application Publication
(10) Pub. No.: US 2016/0163505 A1
(43) Pub. Date: Jun. 9, 2016

(54) HIGHLY CONDUCTIVE NANOCOMPOSITE, BIOLOGICAL AND SMALL MOLECULE MATERIALS FOR ENHANCED RESIN CONDUCTIVITY

(71) Applicant: THE REGENTS OF THE UNIVERSITY OF CALIFORNIA, Oakland, CA (US)

(72) Inventors: Mark H. Ellisman, Solana Beach, CA (US); Donald Johnson, La Jolla, CA (US); Thomas J. Deernick, Del Mar, CA (US); Eric A. Bushong, San Diego, CA (US); Ranjan Ramachandra, San Diego, CA (US); Jay S. Siegel, Zurich (CH)

(21) Appl. No.: 14/905,159

(22) PCT Filed: Jul. 17, 2014
(86) PCT No.: PCT/US2014/047046

§ 371 Date: Jan. 14, 2016

Related U.S. Application Data
(60) Provisional application No. 61/847,402, filed on Jul. 17, 2013.

(51) Int. Cl. H01J 37/28; H01B 1/24; H01B 1/12; H01J 37/22

(52) U.S. Cl. CPC H01J 37/28; H01J 37/22; H01B 1/24; H01B 1/12; H01J 2237/2804

(57) ABSTRACT

A highly conductive nanocomposite material. The material is particularly useful for serial block-face scanning electron microscopy. A polymer resin of the invention is stabilized for conductivity with a conductivity stabilizer selected from one of multi-walled carbon nanotubes, Perylene dianhydride, Hemoglobin, Epoxy-Corannulene, and Bovine Serium Albumin (BSA). The conductivity stabilizer is monodisperse in preferred resins. A preferred nanocomposite material includes a base component of a curable resin, a curing agent or hardener and monomers of carbon containing networks of sp2 hybridized carbon atoms that are dispersed in the base resin. In preferred embodiment, tissue samples are within the resin. Highly effective serial block face scanning electroscopy techniques are provided.

### PRIORITY CLAIM AND REFERENCE TO RELATED APPLICATION

The application claims priority under 35 U.S.C. §119 and applicable treaties from prior provisional application Ser. No. 61/847,402, which was filed Jul. 17, 2013.

### STATEMENT OF GOVERNMENT INTEREST

This invention was made with government support under 5P41GM103412-25 awarded by National Institutes of Health. The government has certain rights in the invention.

### FIELD

Fields of the invention include nanocomposite material and microscopy.

An example application of the invention includes immobilization of tissue samples in Serial Block-face Scanning Electron Microscopy (SBEM).

### BACKGROUND

Serial block-face scanning electron microscopy (SBEM) is a recent microscopy technique that shows great promise for histology and neuroanatomical research by allowing the 3-dimensional reconstruction of relatively large regions of tissue in a “block” form and cell arrays at near nanometer-scale resolution. SBEM employs an automated ultramicrotome fitted into a scanning electron microscope to image a tissue block-face. Samples are prepared by methods similar to those in transmission electron microscopy, typically by staining the specimen with heavy metals then embedding in an epoxy resin. The resin commonly used to immobilize, protect and establish volume uniformity is an insulating material. In SBEM, successive slices are removed from the targeted tissue or the tissue position is changed to change the focus depth in the block and an electron beam is scanned over the remaining block-face or at the new focus depth to produce electron backscatter images. SBEM is useful, for example, to study the 3D ultra-structure of astrocytes, neurons and synapses. A drawback of conventional SBEM is that the resolution obtainable using backscatter electron imaging at low accelerating voltage is modest compared to traditional transmission electron microscopy.

The SBEM imaging technique was introduced by Leighton. See, Leighton, “SEM images of block faces, cut by a miniature microtome within the SEM—A technical note,” Scan. Electron Microsc 2:11 (1981). The SBEM technique was later improved and refined by Denk and Horstmann. See, “SEM images of block faces, cut by a miniature microtome within the SEM—A technical note,” Scan. Electron Microsc, 2:11 (2004).

An SBEM instrument consists of an ultra-microtome fitted within a backscatter-detector equipped SEM. In an automated process, the ultra-microtome removes an ultra-thin section of tissue with an oscillating diamond knife and the region of interest is imaged. This sequence is repeated hundreds or thousands of times until the desired volume of tissue is traversed. This method potentially enables the reconstruction of microns to tenths of millimeters of volumes of tissue at a level of resolution better than that obtainable by light microscopy. In other variations, the tissue is raised to change the focus of the beam, obtaining a virtual slice of the tissue sample.

There are several crucial advantages of SBEM over traditional serial section transmission electron microscopy (SSTEM). The fully automated physical or virtual sectioning process allows very large volumes to be collected with little operator involvement in a fraction of the time required for SSTEM. Because the images are taken directly from the block face prior to each cut or move, section distortion or loss during handling are completely avoided. See, Jurrus “Detection of neuron membranes in electron microscopy images using a serial neural network architecture,” Med. Image Anal. 14:770-783 (2010). Furthermore, because the block is held in place, there are no image shifts. Thus, the images in raw SBEM datasets are already aligned and sequential image stacks are easily combined to create an almost instant 3D reconstruction. An alternative, but conceptually similar approach uses a scanning electron microscope equipped with a focused ion beam (FIB) mounted parallel to the block face for removing (or milling) thin layers of embedded tissue and imaging the milled region (Heymann et al., 2006). See, Knott et al., “Serial section scanning electron microscopy of adult brain tissue using focused ion beam milling,” J. Nerosci 28(12) pp 2959064 (2008). This milling approach removes layers as thin as 15 nm from the block-face. A volume of conventionally prepared adult brain tissue (286 μm³) was imaged at a resolution that allowed for axons and dendrites to be followed and the identification of synaptic connections within the 3D volume. However, the milling process takes longer (minutes) to remove a volume of material when compared to SBEM (seconds), affecting overall throughput.

SBEM has holds promise as an all-in-one volume-imaging microscope for biological specimens, and continues to grow in popularity throughout the biological sciences community. Particular applications include visualization of nervous system ultrastructure, especially in locating and quantifying details in synaptic and other subcellular elements.

### SUMMARY OF THE INVENTION

An embodiment of the invention is a highly conductive nanocomposite material. The material is particularly useful for serial block-face scanning electron microscopy. The material includes a base component of a curable resin, a curing agent or hardener and monomers of carbon containing networks of sp2 hybridized carbon atoms that are dispersed in the base resin. In preferred embodiment, tissue samples are within the resin. The monomers are monodisperse in preferred embodiments. Another resin is stabilized for conductivity with one of multi-walled carbon nanotubes, Perylene dianhydride, hemoglobin, epoxy-corannulene, and Bovine Serium Albumin (BSA). A method of preparing a nanocomposite material includes preparing curable resin without hardener, sonicating a conductivity stabilizer into the resin matrix, infiltrating tissue into the resin, adding hardener, polymerizing the tissue in the resin. In preferred methods SBEM, tissue, cell monolayer, or any biological specimen is prepared in a resin of the invention.

### BRIEF DESCRIPTION OF THE DRAWINGS

FIGS. 1A-1C illustrate a charging problem with a durcupan resin;

FIGS. 2A-2F illustrate small molecules, nanomaterials and metal stabilized proteins of preferred embodiments that can be used to stabilize conductivity of a resin for isolating a tissue sample and conducting SBEM;

FIGS. 3A-3D show the results of quantitative measurement of charge for a preferred embodiment resin using multi-walled carbon nanotubes;

FIGS. 4A-4D compare sample resins of the invention and a depth without tissue and a depth with tissue isolated in the resin;

FIGS. 5A-5C compare preferred embodiment resins and control resins.

### DETAILED DESCRIPTION OF THE PREFERRED EMBODIMENTS

The present inventors have identified specimen charging as a significant limitation to SBEM. When a specimen is “charging,” the electrons from the electron beam that do not get ejected from the specimen have no ability to escape the specimen; thus, collecting “charge” on the surface. To achieve charge balance, the exact number of electrons entering the sample, via the electron beam, must equal the same number of electrons exiting the sample. Therefore, charge balance is another form of defining conductivity for the sample. Sample charging is a significant obstacle to achieving optimal image contrast, resolution and overall volume collection. Sample charging is often caused by poor electrical grounding, or by a highly insulated specimen. Sample charging is often observed in porous tissue samples and cells, where there is exposed resin. Embodiments of the invention improve specimen conductivity and resin conductivity with incorporation of heavy metals and carbon based conductive additives.

In typical SBEM experiments, a nonconductive epoxy based resin is used to immobilized, protect and establish volume uniformity of a sample. The present inventors have identified this as a drawback because electrons from the beam in the SEM collect, and these electrons develop large geometric distortions, or “charging effects” along the surface. These geometric distortions lead to reduced resolution along the surface. The tissue block fluctuates position along the x,y plane, so collecting volumes are largely inconsistent in cases where there is more exposed resin.

The insulating behavior of the epoxy resin in which a specimen is embedded leads to the electrons from the SBEM beam collecting in the resin so that large geometric distortions, or “charging effects” develop along the surface. Eliminating this charging has been identified by the present inventors as a key to removal of image distortions. Embodiments of the invention engineer the electron transport properties of the resin, specifically to make it more conducting. This invention tunes physical properties of a polymer matrix by dispersing nanoscopic, biological, or small molecules therein to form a conductive material. As an added benefit, the degree of dispersion of the nanostructures within the matrix correlates with the optimization of the composite properties [e.g., see S. Pfeifer & P. R. Bandaru (2014): A Methodology for Quantitatively Characterizing the Dispersion of Nanostructures in Polymers and Composites, Materials Research Letters, DOI: 10.1080/21663831.2014.886629]. The right types of nanoscale entities and dispersion parameters and protocols are identified and optimized in embodiments of the present invention to obtain provide resins that have a conductivity suitable for high resolution SBEM and for isolating and penetrating tissue samples within the resin. Preferred embodiment resins are particularly well-suited for the SBEM application, because the nanocomposite formulation is compatible with the features scale of the specimens to be imaged and also with the steps for specimen preparation, and will not lead to any image artifacts.

Embodiments of the invention provide highly conductive nanocomposite, biological and small molecule materials. These materials are particularly useful for serial block-face scanning electron microscopy. The epoxy resin includes a base component of a curable resin, a curing agent or hardener and the conductive material. In a preferred embodiment, tissue samples are embedded in resin. The conductive materials are monodisperse in the preferred embodiments. Each resin is enhanced in conductivity with one of the conductive materials: multi-walled carbon nanotubes (MWCNTs), perylene dianhydride, hemoglobin, epoxy-corannulene monomers, or an unmodified corannulene monomer, and Bovine Serium Albumin (BSA). MWCNTs, corannulene and perylene dianhydride. These materials all assist in making the resin conductive in their rich electron density rich sp2 hybridized carbon atoms. perylene dianhydride provides a preferred embodiment in which the electron density is withdrawn from the aromatic centers by the carbonyl groups. BSA and Hemoglobin rely metals, which stabilize the overall native state of the protein, to provide conductivity to the epoxy-resin

A preferred embodiment of the invention provides a highly conductive material, comprising a base component containing a curable resin, a curing agent or hardener and monomers of carbon containing networks of sp2 hybridized carbon atoms that are dispersed in the base resin. The carbon atoms are small enough to penetrate biological tissue of interest.

A preferred embodiment polymer resin is stabilized for conductivity with a conductivity stabilizer consisting of one of multi-walled carbon nanotubes, perylene dianhydride, hemoglobin, epoxy-corannulene, and Bovine Serium Albumin (BSA)

A preferred embodiment for making a curable resin includes mixing a combination of low and high sterically hindered expoy monomers, an anhydride, and a tertiary amine as the initiator. MWCNTs, corannulene or perylene dianhydride are blended with epoxy monomers and anhydride. Once blended into the mixture, the tertiary amine initiator is blended in to polymerize the epoxy based resin at temperatures 65-70° C. for up to 24 hours. The completed resin material is a hardened material, which is a physical way for confirming completion of the polymerization.

A preferred method for forming a nanocomposite material in a monodispersion is by sonication of corannulene or multi-walled carbon nanotubes with the resin before the curing agent is added. The uniform dispersal and bonding of nanostructures in a polymer may confer unique properties to the composite. Aggregation and bundling can lead to poor interfacial bonding of the structures with the polymer matrix. Bundling is not unexpected for carbon nanotubes and similar carbon nanostructures because strong van der Waals bonding is prevalent in such. To overcome aggregation of MWCNTs, solvent additives coupled with sonication partially overcome van der Waals interactions. Ultrasonification overcomes van der Waals bonding for corannulene and perylene dianhydride. BSA and Hemoglobin are immobilized in a gelatin matrix that is applied to the biological specimen during heavy metal staining The gelatin-immersed biological specimen is then embedded in the resin.

A preferred embodiment for incorporating BSA or hemoglobin into the resin embedded tissue begins before heavy metal staining the specimen. BSA or hemoglobin blended with gelatin and fixatives at 37-40° C. The specimen is therein incubated at 4-6° C. for 2 hours in the mixture. Once incubated, the tissue is washed and carried on to the heavy metal staining procedure.

A method of SBEM includes preparing a tissue, cell monolayer, or any biological specimen for imaging, the specimen is embedded by a highly conductive material comprising: a curable resin, a curing agent or hardener and conductivity stablizer that is dispersed in the base resin; placing the sample in an SBEM; and successively imaging different depths in the sample by iterative ultramicrotome sectioning

Embodiments of the invention include highly conductive nanocomposite, biological, and small molecule materials, fabrication methods for the materials and application of the materials as resins to immobilize tissue samples for Serial Block-face Scanning Electron Microscopy (SBEM). In preferred embodiments, conductivity is enhanced by dispersing monomers of a form of carbon containing networks of sp2 hybridized carbon atoms in the base resin. A preferred embodiment using corannulene or “buckybowl”, a C₆₀ derivative, has been shown in experiments to dramatically improve image contrast and resolution for SBEM at low accelerating voltages. While the invention is not limited by the reason for the enhancement, the enhancement can be attributed to full grounding of the resin and tissue and elimination of charging effects. Tissue immobilization in accordance with the invention overcomes image quality limits of prior SBEM.

Preferred embodiments of the invention use a highly conductive derivative of buckyball known commonly as corannulene or circulene. Buckybowls can be fabricated according to Siegel et al., “Kilogram-Scale Production of Corannulene” Org. Process Res. Dev. 2012, 16, 664-676; and this material is known to have conductive properties “Electron transport and optical properties of curved aromatics,” WIREs Comput Mol Sci 3: 1-12 doi: 10.1002/wcms.1107 (2013). This material is made of a network of sp2-hybridized carbons. The size is advantageous for passing into most open spaces in tissue (i.e. capillaries, blood vessels, vascularized regions, etc.). In eliminating charging effect, corannulene acts as establishing a path of molecular level capacitors across the resin. A resin block can be cut without experiencing any major geometric distortions. As a result, the resin and tissue are fully grounded and do not retain any electrons from the beam dose. In other embodiments, the resin is made conductive with other conductive nanomaterials, e.g., multi-walled carbon nanotubes. The smaller conductive nanomaterial is preferred, but multi-walled carbon nanotubes also provide conductivity to the resin, which enhances microscopy.

Preferred embodied resins use corannulene to stabilize the conductivity of a resin. Corannulene, as a dopant, can be locally associated to another corannulene monomer across the entire resin block. This distance will vary, however, should be within a set distance that defines capacitance across the resin space. As a covalent linker, corannulene is locked into the polymer backbone of the resin, making it uniformed throughout the material. A preferred embodiment exemplary resin closely associates corannulene with a 10% wt concentration of the monomer.

Other embodiments stabilize a resin with multi-walled carbon nanotubes (MWCNT), perylene dianhydride, hemoglobin, epoxy-corannulene, and Bovine Serium Albumin (BSA). Each of these can improve the conductivity of the resin. The MWCNTs has the additional advantage of an anisotropic structure that lends anisotropy to the composite and its properties. This is desirable for particular applications, e.g., directed electric/thermal conductivity.

Preferred embodiments of the invention also provide a specimen preparation protocol employing intense heavy metal staining to substantially improve the contrast and image resolution obtainable by SBEM. The heavy metal staining procedure is designed to covalently link osmium tetroxide to alkene-substituted groups. These groups are commonly found on unsaturated fatty acids. Other metals like iron and lead are also used to treat the specimen during this process. The improvement in staining greatly improves feature resolution and detection in images obtained with 2.0 keV and below. This increase in metal concentration within the resin-embedded specimens also makes them sufficiently conductive to eliminate some need for variable pressure SBEM. As a significant further step, the invention introduces the approach of improving resin conductivity in highly porous specimens; in a preferred embodiment, this is enabled by the use of corannulene, a C₆₀ derivative, or any other conductive material. With the resin conductivity thus enhanced, dramatic improvements can be achieved in feature resolution and detection in images obtained at 5 keV accelerating voltage and below. The invention, used in conjunction with heavy metal staining, greatly improves imaging for large-scale three-dimensional reconstruction of neuronal tissue.

A preferred embodiment is a highly conductive nanocomposite material. The material includes a base component containing a curable resin, a curing agent or hardener and monomers of carbon containing networks of sp2 hybridized carbon atoms that are dispersed in the base resin. In preferred embodiments, the sp2 hybridized carbon are one of corannulene, perylene dianhydride and multi-walled carbon nanotubes. In preferred embodiments, the sp2 hybridized carbon atoms are monodisperse in the base resin. A preferred sp2 hybridized carbon is an aromatic conjugated structure.

Preferred embodiment resins include corannulene or multi-walled carbon nanotubes with dispersion are of 5% wt, or 2% wt concentration, respectively in the base resin.

Preferred embodiments include corannulene in the 6-10 angstroms range in size range, which passes open spaces in mouse tissue.

Preferred embodiments include multi-walled carbon nanotubes 5-10 nm in diameter and 20-30 microns in length.

Preferred embodiments provide nanocomposite material composition of with resistance of coranulene in the 1-3 kΩ range (given an applied voltage of 100 volts at ambient conditions).

Preferred nanocomposite resis provide resistance with multi-walled carbon nanotubes is in the 25-40 kΩ range (given an applied voltage of 100 volts at ambient conditions).

Preferred embodiment resins are used in Serial Block-face Scanning

Electron Microscopy (SBEM) to immobilize tissue samples.

A method of preparing the nanocomposite material includes preparing curable resin without hardener, sonicating corannulene or multi-walled carbon nanotubes, into resin matrix, infiltration tissue, adding hardener, and polymerization of the tissue in resin.

In preferred methods corannulene or multi-walled carbon nanotubes, are added and sonicated at 5% wt, or 2% wt, respectively, once dispersed, the nanocomposite material composition are separated into a 50% wt ethanol/50% wt resin and a 100% wt resin, where the resin has been mixed with corannulene or multi-walled carbon nanotubes, and the 50% wt ethanol/50% wt resin solution is used to infiltrate biologically tissue that has been incubating in 100% ethanol.

In preferred methods the biological tissue comprises heavily metal stained tissue that is incubated with 50% wt ethanol/50% wt resin solution, e.g. for 18 hours, and the incubated in the 100% wt resin solution, e.g., for 48 hours, and then embedded in a 100% wt resin solution that has the hardener component added, e.g., 0.1 g for every 21.4 g of 100% resin solution, added, and then cured, e.g., for 72 hours at >65° C.

Highly conductive resins for SBEM have dispersed carbon that establish paths of molecular level capacitors across the resin to eliminate charging effect. Resins of the invention permit SBEM with fully grounded resin and tissue sample. The sample and resin do not retain electrons from the beam dose.

With a preferred highly conductive resin for SBEM, wherein corannulene is dispersed in many open areas of tissue, where there is only resin.

With a preferred highly conductive resin for SBEM, multi-walled carbon nanotubes is partially dispersed in open areas of tissue, where there is only resin.

A method of SBEM arranges the tissue to be imaged at 7-10 mm working distance, detecting backscatter electrons, at 2.6-5.0 keV accelerating volts in high vacuum enables image high resolution/contrast.

A method of SBEM uses scan rate and dwell times that are slower than conventional techniques, which are between 4-12 microseconds per line of pixels, and the bias is left on for optimal measurements.

A method of SBEM includes preparing a tissue, cell monolayer, or any biological specimen for imaging, the sample being immobilized by a highly conductive material comprising a base component containing a curable resin, a curing agent or hardener and any one of the present conductive materials, that are dispersed in the base resin. The sample is placed in an SBEM microscope. The sample is successively imaged at different depths in the sample. In a preferred embodiment, the different depths are achieved by automated sectioning with a diamond knife in the SBEM chamber.

Preferred embodiments of the invention will now be discussed with respect to the drawings and with respect to experiments that demonstrate preferred embodiments of the invention. Artisan will appreciate broader aspects of the invention from the experiments.

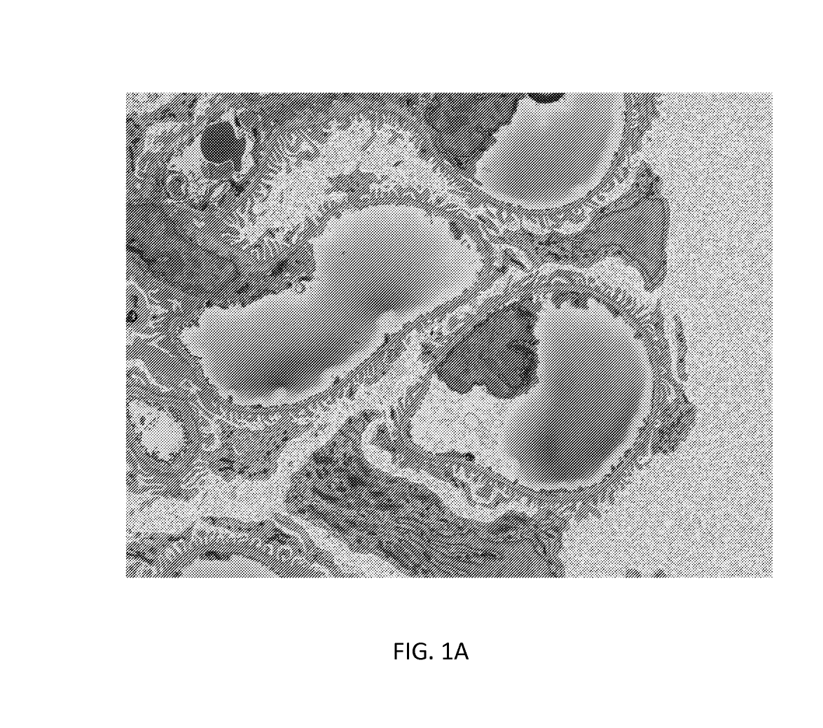

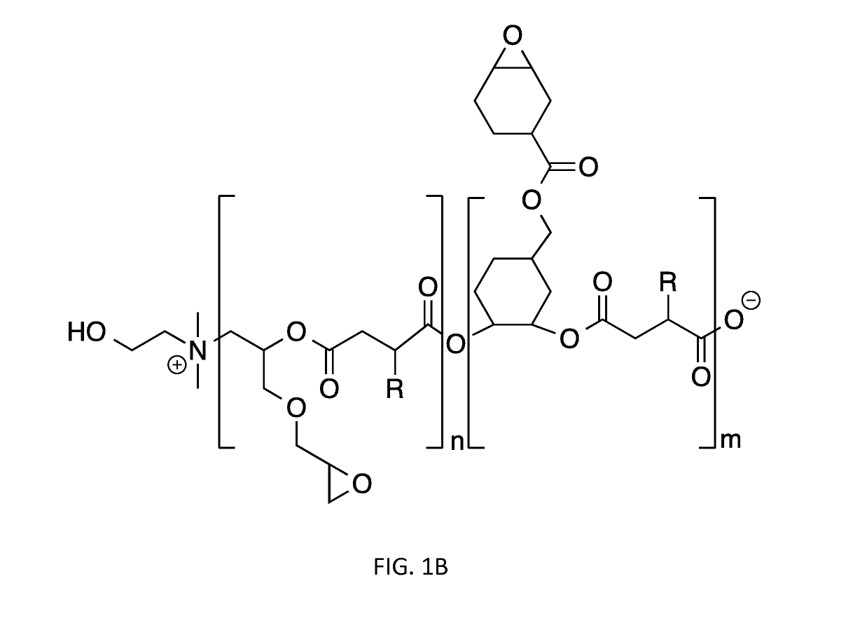

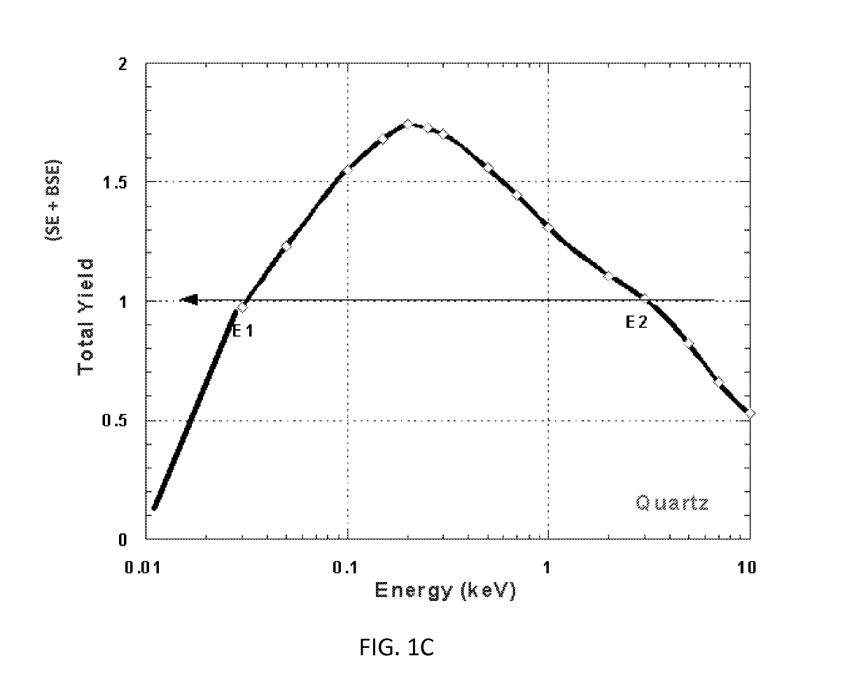

FIG. 1A illustrates the problem that occurs with charging in a tissue sample in an epoxy-based resin. Specifically, in sample areas where there is no metal stained tissue, like in the Bowman's Capsule, charged particles are retained on the surface of the resin. FIG. 1B illustrates an already polymerized, but not crosslinked, epoxy resin. As demonstrated in FIG. 1B, the epoxy resin is a highly cross-linked material that has been polymerized by a tertiary amine initiator. With any of the additives mentioned in the preferred embodiments, the resin is not conductive. As shown in FIG. 1C, “charging” can be quantified by collecting the total secondary and backscatter electron yields are measured at a given set of landing energies. When the total yield=1, the resin is dissipating charge as fast as it is collected, otherwise known as charge balance.

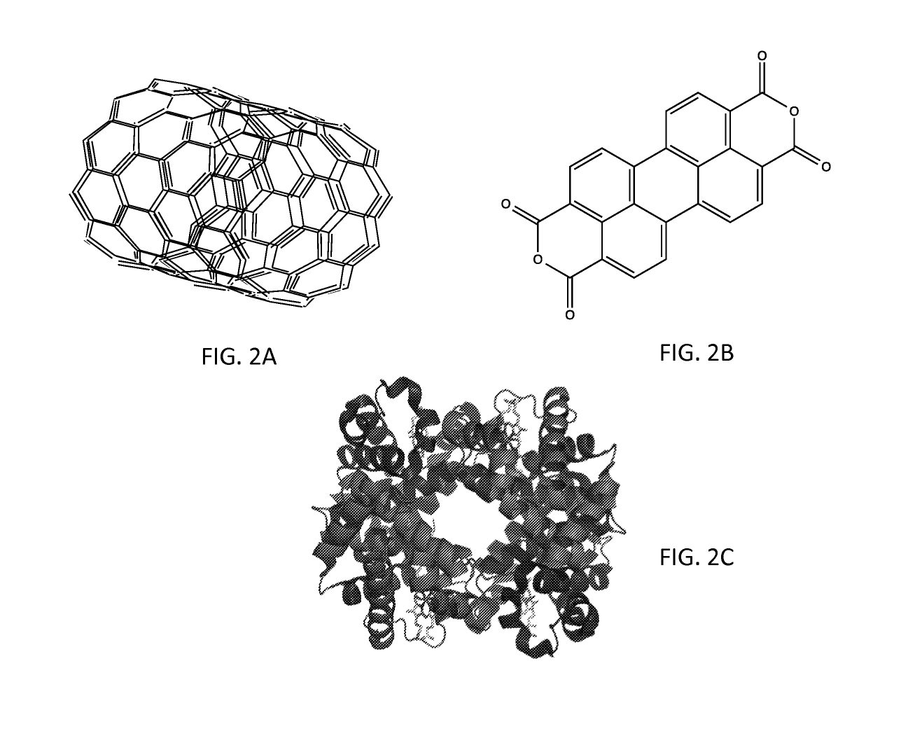

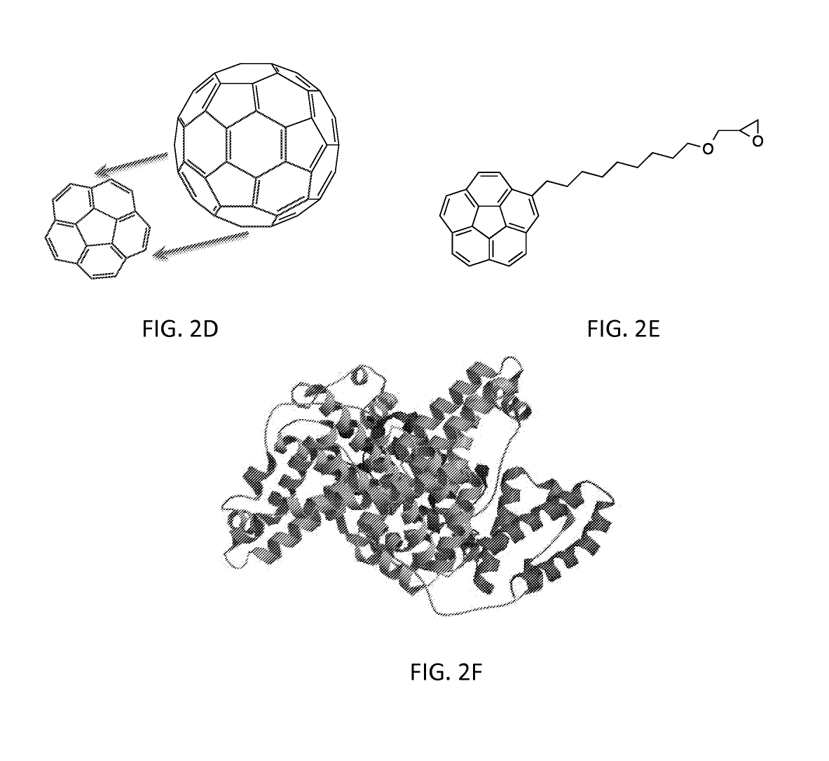

FIGS. 2A-2F illustrate small molecules, nanomaterials and metal stabilized proteins that have been demonstrated to improve and stabilize resin conductivity. FIG. 2A illustrates a multi-walled carbon nanotube structure. FIG. 2B shows perylene dianhydride. FIG. 2C shows hemoglobin. FIG. 2D shows corannulene (in the form of a “buckball” of corannulene derived from C60). FIG. 2E shows epoxy-corannulene. FIG. 2F shows Bovine Serium Albumin (BSA).

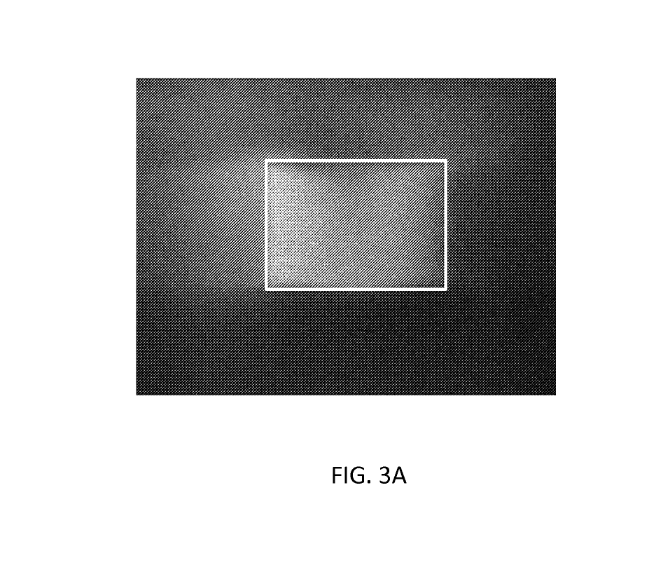

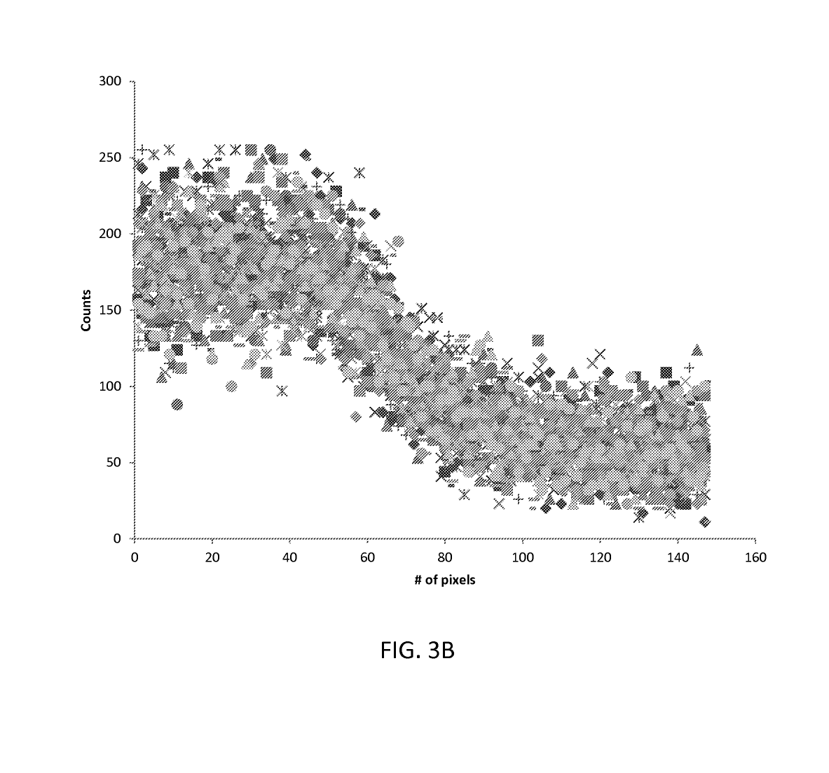

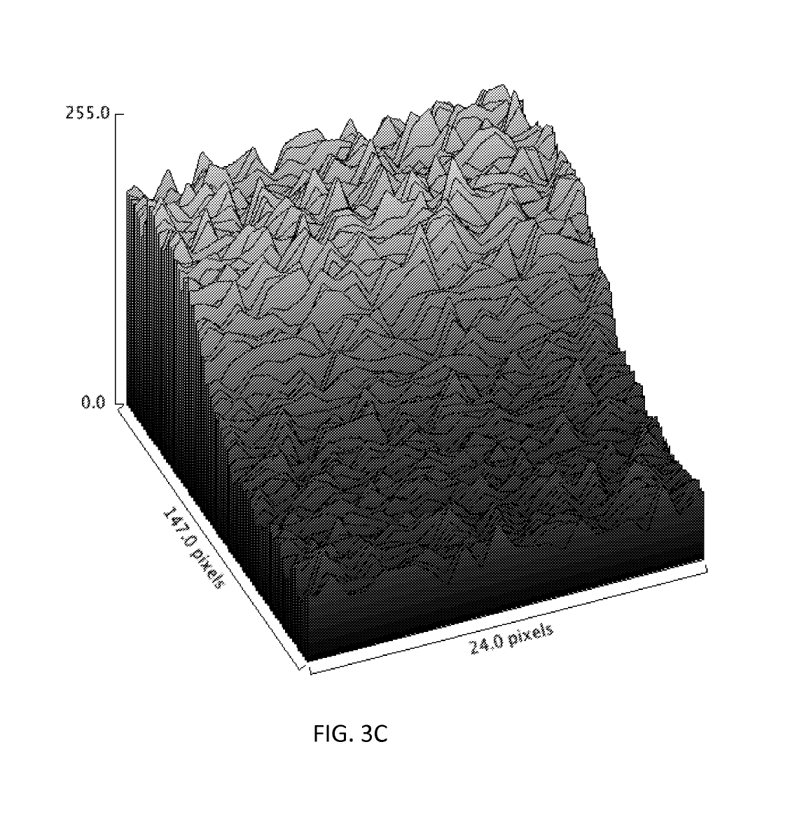

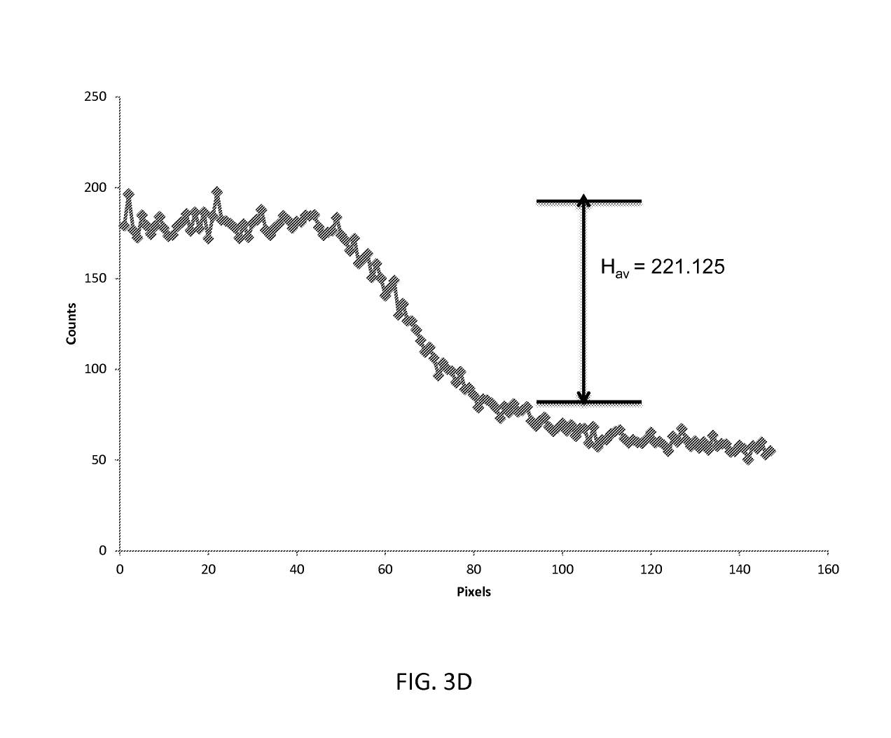

Experiments measured charging quantitatively in resins stabilized for conductivity. Particular example epoxy resins included a combination of low and high sterically hindered epoxy monomers, an anhydride, and a tertiary amine as the initiator. MWCNTs, corannulene or perylene dianhydride are blended with epoxy monomers and anhydride. FIGS. 3A-3D show the results of applying edge function analysis to charged/non-charged SEM images of resin. The resin was doped with MWCNTs in FIGS. 3A-3D. Charging is quantitatively measured by collecting the pixel intensity along the edge of a dosed area, as shown by the edge of the rectangle in FIG. 3A. The distribution of various point intensities are graphed in FIG. 3B and collected in FIG. 3C. The average intensity for selected edge along the dosed area is calculated in FIG. 3D, and gives a binary measure of charging in the material. FIG. 3D illustrates that Hₐᵥ=221.125, which is our relative measure of charging. The electron micrographs were collected by the following protocol: (1) the resin is imaged at a set beam dose at 10 kX magnification, (2) followed by lowering the magnification to 5 kX, and (3) collecting the final image. As a relative measure of charging, the resin conductivity is not specifically being measured. This measurement only determines whether the resin is conductive, or not. So, edge function analysis is not an absolute measure of conductivity in for the epoxy resin blocks, but a binary measurement. As a result, hemoglobin, BSA and perylene dianhydride doped resin blocks have been tested by this method for conductivity.

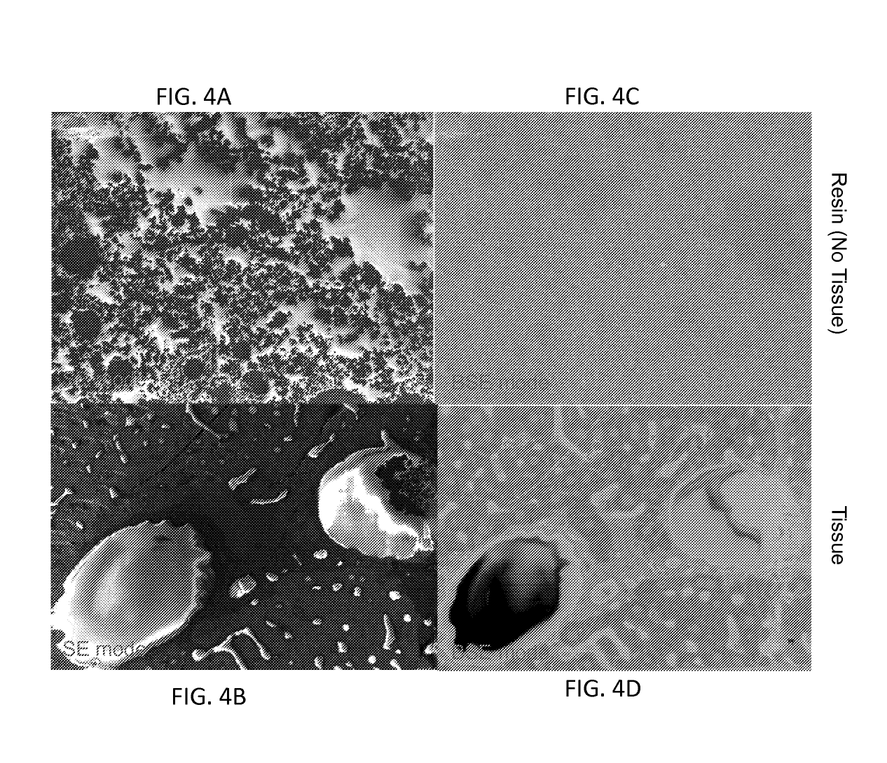

In experiments where epoxy resins blocks were prepared with multi-walled carbon nanotubes (MWCNTs), the resins were sectioned, imaged and tested by edge function analysis. An epoxy resin block is usually tested for charging by SBEM, as shown in FIG. 4A and 4C, where no tissue is in respective viewing by secondary electron (SE) and backscatter electron effects (BSE). In the SE image, black “hair ball” like structures are the multi-walled carbon nanotubes. When compared to the BSE image, the MWCNTs are localized in areas where there is reduced charging. As the sample was sectioned, we reached areas where the brain tissue was exposed, as shown in FIGS. 4B and 4D, where the brain tissue is being imaged by secondary electron (SE) and backscatter electron (BSE) detectors. At this segment in the epoxy resin block, two blood vessels are exposed. The blood vessel in FIG. 4B on the left is not doped with any MWCNTs; whereas, the blood vessel on the right is doped with MWCNTs. As shown in FIG. 4D, the charging is reduced, if not present, in the right blood vessel while the left blood vessel is charging. The brain tissue used in this measurement came from a male C57BLK6 mus musculus (mice). The variability in dispersal of the material is a large reason for suggesting corannulene, BSA, hemoglobin and perylene dianhydrides for the embedding in biological specimens for serial block-face scanning electron microscopy.

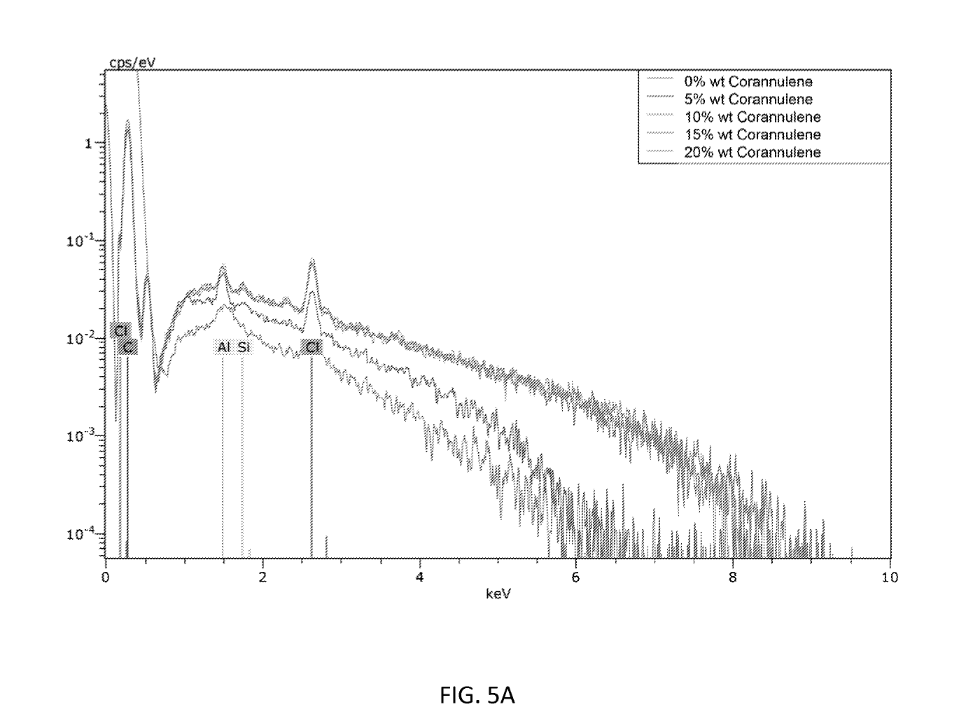

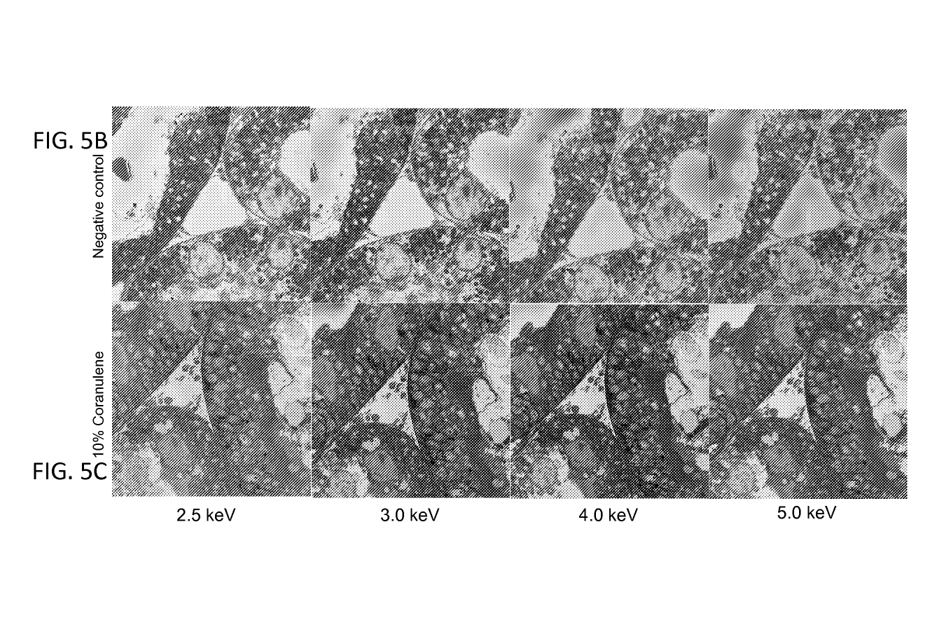

Experiments were conducted with various percent weights of corannulene in resin. The percent weight of corrannulene was varied from 0% (lowest trace in FIG. 5A) to 20% (highest trace in FIG. 5A). As shown in FIG. 5A, the absolute measure of charging is obtained by energy dispersive spectroscopy (EDS) scanning electron microscopy (SEM). As shown by Newbury et al. 2004, “Assessing Charging Effects on Spectral Quality for X-ray Microanalysis in Low Voltage and Variable Pressure/Environmental Scanning Electron Microscopy” Microsc. Microanal. 10, 739-744, (2004), specimen charging can be quantitated by measuring the Duane-Hunt limit, or drop off in landing energies. As the specimen conductivity is improved, the Duane-Hunt limit approaches the theoretical landing energies set by the instrument. In FIG. 5A, corannulene is doped into the resin at increasing concentrations as a technique to measure the degree of charging versus edge function analysis that only defines whether the resin is charging, or not. As we increase in concentration, the specimen charging decreases, corresponding to an increase in specimen conductivity. At 10% wt corannulene, the charging seems to reach the limit of charge reduction. From this figure, one could also infer that the actual critical concentration for charge reduction is between 5 and 10% wt. As a result, kidney tissue specimens, from a male C57BLK6 mus musculus (mice), were used to test 10% corannulene versus a control sample with no conductive additive under the serial block-face scanning electron microscope, as shown in FIG. 5B. The tissue area was selected to consistently qualitatively test charging between the two samples for a number of voltages from 2.5 keV to 5.0 keV. For the 10% corannulene specimen, improved reductions in charging were consistent with the improvements demonstrated by EDS-SEM. So, the results in FIGS. 5A and 5B show the improved conductivity of the corannulene-doped resin.

While specific embodiments of the present invention have been shown and described above and are apparent from the claims and the additional description in the attachments that follow the claims, it should be understood that other modifications, substitutions and alternatives are apparent to one of ordinary skill in the art. Such modifications, substitutions and alternatives can be made without departing from the spirit and scope of the invention, which should be determined from the appended claims.

Various features of the invention are set forth in the appended claims.

1. A highly conductive nanocomposite material, comprising a base component containing a curable resin, a curing agent or hardener and monomers of carbon containing networks of sp2 hybridized carbon atoms that are dispersed in the base resin.

2. The nanocomposite material composition of claim 1, comprising a tissue sample immobilized in the resin and infiltrated by the monomers of carbon.

3. The nanocomposite material composition of claim 1, wherein the sp2 hybridized carbon comprises one of corannulene and multi-walled carbon nanotubes.

4. The nanocomposite material composition of claim 1, wherein the sp2 hybridized carbon atoms are monodisperse in the base resin.

5. The nanocomposite material composition of claim 1, wherein the sp2 hybridized carbon is an aromatic conjugated structure.

6. The nanocomposite material composition of claim 1, wherein the corannulene or multi-walled carbon nanotubes are of 5% wt, or 2% wt, concentration, respectively, in the base resin.

7. The nanocomposite material composition of claim 1, wherein the monomer of carbon comprises corannulene in the 6-10 angstroms size range, structured to passing most open spaces in mouse tissue.

8. The nanocomposite material composition of claim 1, wherein the monomer of carbon comprises multi-walled carbon nanotubes 5-10 nm in diameter.

9. The nanocomposite material composition of claim 1, wherein the monomer of carbon comprises coranulene in the 1-3 kΩ range (given an applied voltage of 100 volts at ambient conditions).

10. The nanocomposite material composition of claim 1, wherein the monomer of carbon comprises multi-walled carbon nanotubes in the 25-40 kΩ range (given an applied voltage of 100 volts at ambient conditions).

11. A method of preparing a nanocomposite material composition comprising preparing curable resin without hardener, sonicating monomers of carbon containing networks of sp2 hybridized carbon atoms into resin matrix, infiltrating tissue into the resin, adding hardener, polymerizing the tissue in the resin.

12. The method of claim 1, wherein the monomers of carbon comprises corrannulene or multi-walled carbon nanotubes.

13. The method of claim 12, wherein the corannulene or multi-walled carbon nanotubes are added and sonicated at 5% wt, or 2% wt, respectively, and after dispersion, the nanocomposite material composition is separated into a 50% wt acetone/50% wt resin and a 100% wt resin, where the resin has been mixed with corannulene or multi-walled carbon nanotubes, and the 50% wt acetone/50% wt resin solution is used to infiltrate biologically tissue that has been incubating in 100% acetone.

14. The method of claim 13, wherein the biological tissue comprises heavily metal stained tissue.

15. A method of SBEM using the highly conductive resin of claim 1, wherein the tissue is imaged at 7-10 mm working distance, and detecting back-scatter electrons, at 2.6-5.0 keV accelerating volts in high vacuum enables image high resolution/contrast.

16. A method of SBEM using the highly conductive resin of claim 1, wherein the scan rate and dwell times are slower than 4-12 microseconds per line of pixels, and the bias is left on for optimal measurements.

17. A method of preparing a nanocomposite material, comprising:
preparing curable resin without hardener;
dispersing a conductivity stabilizer into the resin matrix;
infiltrating a biological specimen into the resin;
adding hardener; and
polymerizing the tissue in the resin.

18. The method of claim 17, wherein the conductivity stabilizer comprises one of corannulene and perylene dianhydride and said dispersing comprising ultrasonification

19. The method of claim 17, wherein the conductivity stabilizer comprises one of BSA and Hemoglobin and said dispersing comprises first immobilizing the biological specimen in a gelatin matrix of the conductivity stabilizer and then conducting heavy metal staining and then embedding the gelatin-immersed biological specimen into the resin.

20. The method of claim 19, wherein the having metal staining covalently links osmium tetroxide to alkene-substituted groups.

21. The method of claim 19, wherein the having metal staining comprises staining with iron and/or lead.

22. The method of claim 17, wherein the biological specimen is tissue or a cell monolayer.

23. The method of claim 17, wherein said preparing comprises mixing a combination of low and high sterically hindered expoy monomers, an anhydride; said dispersing comprises blending multi-walled carbon nanotubes, corannulene or perylene dianhydride with the epoxy monomers and anhydride, and said adding comprises adding a tertiary amine as an initiator.

24. The method of claim 23, wherein said polymerizing is conducted at temperatures of 65-70° C. for up to 24 hours.

25. A method of SBEM, comprising:
forming a 3D tissue sample for imaging, the sample being immobilized by a highly conductive nanocomposite material comprising a base component containing a curable resin, a curing agent or hardener and a conductivity stabilizer dispersed through the material;
placing the sample in an SEM microscope; and
successively imaging different depths in the sample.

26. The method of claim 25, wherein said successively imaging comprises virtually imaging different depths by focusing a different level.

27. The method of claim 25, wherein said successively imaging comprises physically sectioning the sample.

28. The method of claim 27, wherein the physical sectioning comprises automated sectioning with a diamond knife in an SBEM chamber.

29. The method of claim 27, wherein the conductivity stabilizer comprises one of multi-walled carbon nanotubes, perylene dianhydride, hemoglobin, epoxy-corannulene, and Bovine Serium Albumin (BSA)

30. A resin stabilized for conductivity with a conductivity stabilizer consisting of one of multi-walled carbon nanotubes, perylene dianhydride, hemoglobin, epoxy-corannulene, and Bovine Serium Albumin (BSA).

31. The resin of claim 30, wherein the conductivity stabilizer is monodisperse in the resin.

32. The resin of claim 30, wherein the resin comprises a combination of low and high sterically hindered epoxy monomers, an anhydride, and a tertiary amine as the initiator.
